(19) United States
(12) Patent Application Publication
(10) Pub. No.: US 2026/0005065 A1
(43) Pub. Date: Jan. 1, 2026

(54) DUMMY COMPONENTS IN INTEGRATED CIRCUITS

(71) Applicant: Texas Instruments Incorporated, Dallas, TX (US)

(72) Inventors: James Robert Todd, Plano, TX (US); Umamaheswari Aghoram, Richardson, TX (US); Scott A. Johannesmeyer, Richardson, TX (US); Mona Eissa, Allen, TX (US); Nikhil Rangaraju, Dallas, TX (US); Maja Imamovic, Rowlett, TX (US)

(21) Appl. No.: 18/759,943

(22) Filed: Jun. 30, 2024

(51) Int. Cl. H01L 21/762; H01L 21/763; H01L 21/8234; H01L 27/088; H01L 29/78

(52) U.S. Cl. CPC H01L 21/76205; H01L 21/76224; H01L 21/763; H10D 84/0151; H10D 84/038; H10D 84/83; H10D 30/65

(57) ABSTRACT

Described examples include an integrated circuit having a substrate. The integrated circuit also has at least one dummy cell on the substrate, the dummy cell having at least a first component having an edge in a first layer of components on the substrate and at least a second component in a second layer of components, the second layer of components on the first layer of components and the substrate, wherein no part of the second component is proximate to the edge of the first component. The integrated circuit also has an insulating layer on the first layer of components and the second layer of components, the insulating layer having a first surface opposite to a second surface of the insulating layer on the first layer of components and the second layer of components, wherein the first surface is planarized and a patterned conductor layer on the first surface.

### TECHNICAL FIELD

This relates generally to integrated circuit design and fabrication, and in particular examples to design and fabrication of high-voltage integrated circuits.

### BACKGROUND

Integrated circuit fabrication involves forming many patterned layers of materials. When etching or chemical/mechanical polishing, the material that is removed is monitored to help determine the etching endpoint. With high voltage devices, bond pads and test pads require large buffer areas where no active device can be formed. However, in the buffer areas, if there are no dummy elements corresponding to the elements in the active area, the material removed from the buffer areas can provide false endpoint detection signals. To facilitate endpoint detection when etching, dummy components may be formed in unused areas of the wafer.

### SUMMARY

In accordance with an example, an integrated circuit includes a dummy cell over a semiconductor substrate. The dummy cell includes an epitaxial region located within an opening in a shallow trench isolation (STI) region that extends into the substrate, a local oxidation of silicon (LOCOS) region having a bird's beak at a perimeter of the LOCOS region, and a polysilicon structure over the substrate. The polysilicon structure is located relative to the LOCOS region such that a perimeter of the polysilicon structure never crosses the perimeter of the LOCOS region.

In accordance with another example, a method of forming an integrated circuit includes forming dummy cell over a semiconductor substrate. Forming the dummy cell includes forming an ST) region extending into the semiconductor substrate, forming a LOCOS region over the semiconductor substrate, and forming a polysilicon structure over the substrate. The polysilicon structure is located relative to the LOCOS region such that a perimeter of the polysilicon structure and a perimeter of the LOCOS region do not intersect.

### BRIEF DESCRIPTION OF THE DRAWINGS

FIG. 1 is a side view of a simplified example laterally diffused metal-oxide semiconductor (LDMOS) transistor.

FIG. 2 is a simplified plan view of an example integrated circuit.

FIGS. 3A and 3B are plan view and side view diagrams, respectively, of an example dummy structure.

FIG. 4 is a side view of a dummy cell illustrating an issue with this type of dummy cell.

FIG. 5 is lumped element model of capacitances in the dummy cell of FIG. 4.

FIGS. 6A-6C, 7A-7B and 8A-8B are views of example dummy cell configurations.

### DETAILED DESCRIPTION

In the drawings, corresponding numerals and symbols generally refer to corresponding parts unless otherwise indicated. The drawings are not necessarily drawn to scale.

In this description, the terms “on” and “over” may include layers or other elements where intervening or additional elements are between an element and the element that it is “on” or “over.”

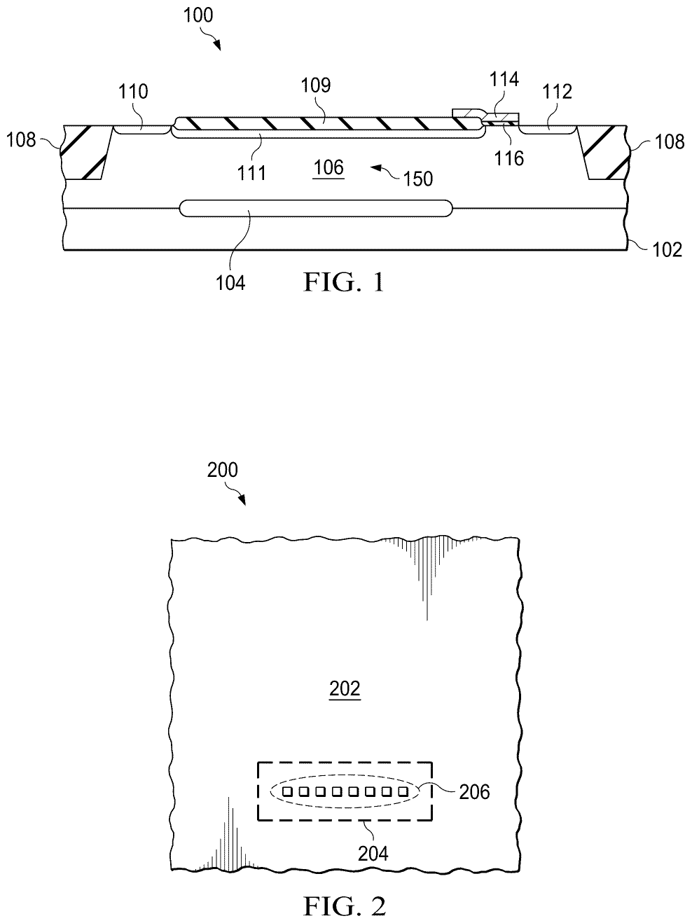

FIG. 1 is a simplified side view of an example laterally diffused metal-oxide semiconductor (LDMOS) transistor 100. LDMOS transistor 100 is formed in an epitaxial layer 106, which is formed on substrate 102. Shallow trench isolation (STI) 108 separates LDMOS transistor 100 from other devices in epitaxial layer 106 and substrate 102. Gate 114 controls current from source 112 to drain 110 using a field across gate dielectric 116. To help control voltage gradients within the extended drain, a reduction of surface gradients (RESURF) diffusion 111 is implanted before formation of local oxidation of silicon (LOCOS) layer 109. A buried RESURF layer 104 may also be included.

The very high voltages applied to LDMOS transistors such as LDMOS transistor 100 must be designed to avoid localized high voltage gradients in extended drain 150 as much as possible. A local breakdown can trigger an avalanche effect that destroys the transistor. RESURF regions help redirect electric fields in the lateral drain to help avoid these localized high voltages. The structure with RESURF diffusion 111 with LOCOS layer has proven very helpful in avoiding these localized high voltages. However, LOCOS layers expand up as well as into epitaxial layer 106 as they are being formed. However, to provide high-accuracy photolithography, the surface on which the photoresist is applied must be as planar as possible. In the example transistor 100, LOCOS layer 109 is formed by oxidizing the surface of epitaxial layer 106 in an oxygen ambient at a temperature of 700-1100° C. for 120-240 minutes. This produces a LOCOS layer 109 of about 200-500 nm. Of this thickness, a little more than half (75-250 nm) will be above the surface of epitaxial layer 106. Given that the dielectric above LDMOS transistor 100 (not shown) that separates the devices in the epitaxial layer from the first level of metal (not shown) is only about 450-600 nm, the non-planarity caused by LOCOS layer 109 means that, after planarization, the dielectric between the gate 114 and the first level metal is relatively thin. This causes some surprising issues in dummy cell structures as is more fully explained hereinbelow.

FIG. 2 is a simplified plan view of an example integrated circuit 200. Active area 202 is where functional devices, such as LDMOS transistors, are formed. Probe pads 206 are formed in buffer area 204. Leads (not shown) extend from probe pads 206 to desired connection points in the devices in active area 202. For high voltage devices, buffer area 204 is large to avoid fields from the applied voltages affecting devices near or under probe pads 206. Similar buffer areas are provided for bond pads (not shown). The purpose of FIG. 2 is to illustrate that there are buffer areas where no active devices can be formed.

The buffer area 204 and similar buffer areas can be problematic in fabricating the device. For example, when etching features of the active devices, the material removed by the etchant may be monitored to determine an endpoint of the etch process. For instance, when performing a plasma etch of a polysilicon layer (sometimes referred to as “polysilicon”) to form gate 114 (FIG. 1), the presence of silicon dioxide in the plasma may be monitored to help determine when the polysilicon is removed from LOCOS layer 109. Were the buffer area 204 free of dummy devices, the exposed surface of the buffer area 204 may be a silicon dioxide layer, such as a gate oxide layer, otherwise underlying the polysilicon layer in the active area 202. Such a situation may make accurate endpoint detection of the etch process more difficult.

An “areal density” is defined as the ratio of area occupied by features to be formed in a material layer of the integrated circuit 200 to the total, or “global” area of the integrated circuit 200, and may be expressed as a percentage reflecting the fraction of the total area of the integrated circuit 200 occupied by such features. It is desirable that the areal density at a particular material level of the integrated circuit 200 be within a window, or sometimes to exceed a minimum value, that results in acceptably uniform processing of that material layer, e.g. by accurate endpoint detection. For example, uniformity of an etch process may be benefited by a relatively uniform placement of features remaining after the etch process and by at least about 80% of the area of the integrated circuit occupied by a combination of device features and dummy features at that level. Similarly, uniformity of a metal chemical-mechanical polishing (CMP) process may benefit from a fractional areal coverage of metal features produced by the CMP process in a range from 70% to 90%. When device features are not present at a local or global density sufficient to provide the desired level of process uniformity, dummy features that are not part of a device may be placed within areas that would otherwise be open or unoccupied by the material layer of interest. While uniformity of feature (device plus dummy) local density is preferable, the local areal density need not be precisely uniform.

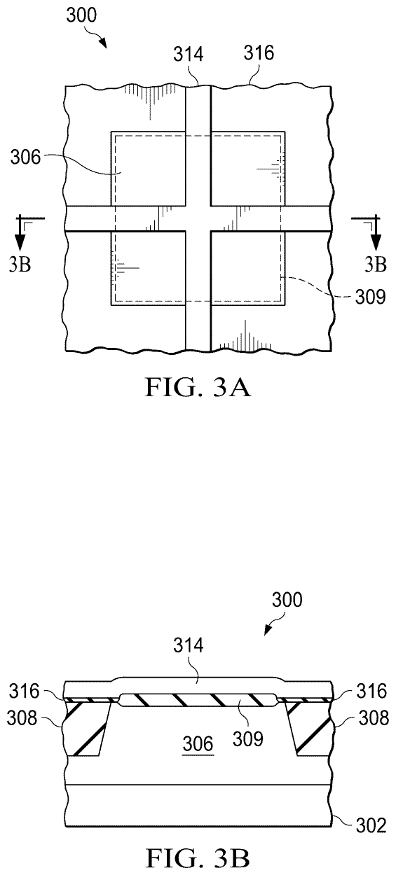

FIGS. 3A and 3B (collectively “FIG. 3”) are plan view and side view diagrams, respectively, of one type of dummy cell structure 300 that is representative of a baseline dummy cell. The dummy cell structure 300 includes an STI layer 308, a LOCOS layer 309 and a polysilicon payer 314 over an epitaxial layer 306. The epitaxial layer 306 extending into the substrate between the STI portions is sometimes referred to as MOAT, and may be doped consistent with doping of active regions of the device of which the dummy cell structure is a part. The components of dummy cell structure 300 correspond to components of transistor 100 (FIG. 1) as shown in the table below. In addition, the components of structure 300 are formed at the same time and using the same processing steps as their corresponding component in transistor 100. In the example of the integrated circuit 200, a dummy cell structure such as the dummy cell structure 300 may appear within the active area 202 or the buffer area 204.

| | |
|---|---|
| Transistor 100 | Dummy cell structure 300 |
| STI 108 | STI 308 |
| Epitaxial layer 106 | Epitaxial layer 306 |
| LOCOS layer 109 | LOCOS layer 309 |
| Gate dielectric 116 | Gate dielectric 316 |
| Gate 114 | Polysilicon layer 314 |
| Substrate 102 | Substrate 302 |

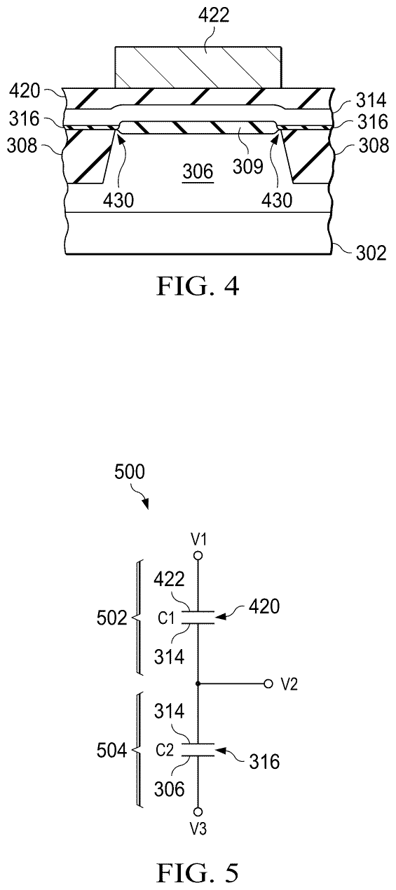

FIG. 4 is a side view of the dummy cell structure 300 in which like numbers in FIG. 3B and FIG. 4 refer to like features. In addition to the components of FIG. 3B, FIG. 4 includes a pre-metal dielectric (PMD) 420 and a metal lead 422 overlying the LOCOS 309 at a first metal level. In the active area 202 the metal lead 422 may be a signal trace and would typically be low-voltage, whereas in the buffer area 204 the metal lead 422 may be a bond pad or a probe pad, or a trace connected to a bond pad or probe pad, that may be at a higher voltage. The pre-metal dielectric 420 may be a dielectric layer deposited by chemical vapor deposition of tetraethyl orthosilicate (TEOS) or another deposited silicon dioxide layer, for example. After deposition, the pre-metal dielectric 420 will conform to the raised portion created by LOCOS layer 309 and polysilicon layer 314. To provide a planar surface for further processing, pre-metal dielectric 420 is then planarized by chemical/mechanical polishing (CMP). In the resulting structure, pre-metal dielectric is significantly thinner above LOCOS layer 309. First level metal lead 422 is then formed by depositing and patterning a metal such as aluminum or a composite copper stack. In this example, first level metal lead 422 connects a probe (or test) pad 206 (FIG. 2) to a test point in the active area 202 (FIG. 2). In alternative examples, first level metal lead may be connected to a bond pad that provides an input to or output from active devices in active area 202 (FIG. 2).

Normally, dummy cell structures do not affect the operation of a device because the dummy cell structures are not connected to any active devices. The inventors of this application made the surprising discovery that this is not always the case. In particular, in the case that the dummy cell structure 300 is located in the buffer area 204 dielectric breakdown of the PMD 420 between the polysilicon layer 314 and the metal lead 422 and/or between the polysilicon layer 314 and the metal lead 422 and the substrate 302.

FIG. 5 shows a lumped-element electrical circuit 500 that illustrates the principles of the dielectric breakdown. Circuit 500 includes two series coupled capacitors, capacitor 502 with capacitance C1, and capacitor 504 with capacitance C2. Regarding the capacitor 502, a first plate corresponds to the metal lead 422 (FIG. 4), a second plate corresponds to the polysilicon layer 314 (FIGS. 3 and 4). For the capacitor 504, a first plate corresponds to the polysilicon layer 314, and a second plate corresponds to the epitaxial layer 306. The LOCOS layer 309 acts as the capacitor dielectric of the capacitor 502, and the gate dielectric 316 acts as the capacitor dielectric of the capacitor 504. notably, the LOCOS layer 309 has a thin “bird's beak” 430 (FIG. 4) that surrounds LOCOS layer 309. Also of note, FIG. 4 is not drawn to scale and overstates the thickness of the gate dielectric 316. The thinness of the bird's beak 430 and gate dielectric 316, in combination with the corner formed by the polysilicon layer 314 at the bird's beak results in the possibility of high electric field strength at this location.

While precise calculation of C1 and C2 is computationally difficult due the irregular thickness of LOCOS layer 309 and pre-metal dielectric 420, it has been estimated that C1 may be about three times C2 due to the large area of thin dielectric between the metal lead 422 and the polysilicon layer 314. For a given voltage, the charge on the polysilicon layer 314 is expected to be equal and opposite the charge on the metal lead 422, and equal and opposite the charge on the epitaxial layer 306. Since the voltage on a capacitor is the charge on the capacitor times its capacitance, the voltage difference |V1-V2| will be approximately three times the voltage difference |V3-V2|.

In an example in which the metal lead 422 is a test or probe pad, sometimes a potential difference such as 70V is placed on the metal lead 422 (V1) with respect to the epitaxial layer (V3). In such case, the voltage between the first level metal lead 422 and the polysilicon layer 314 may be approximately 50 V. This voltage may break down the thin portion of pre-metal dielectric 420. Such a breakdown may then put the entire 70 V across LOCOS layer 309, including the bird's beak 430, which then would then be likely to breakdown as well, causing a short between the metal lead 422 and the epitaxial layer 306 and possibly causing the device of which the dummy cell structure 300 is a part to fail. Although the present example involves a test pad, this weakness can manifest on any lead that passes over a dummy cell in the active area 202 or the buffer area 204 (FIG. 2).

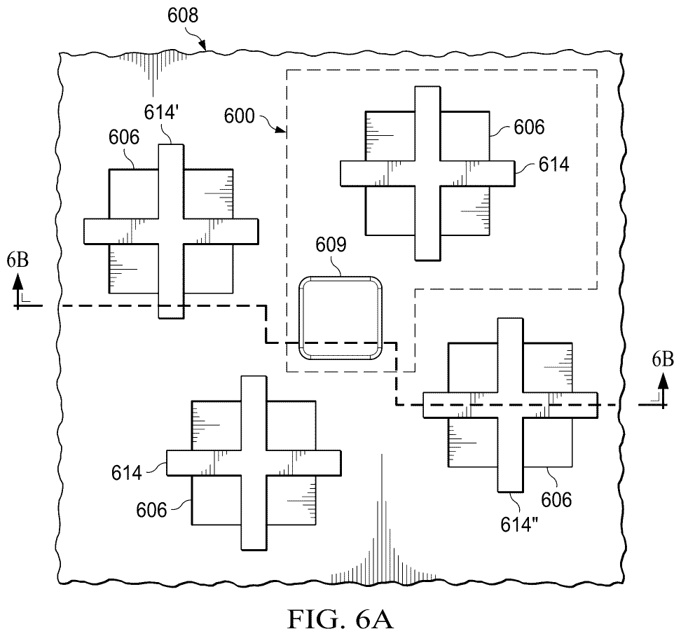

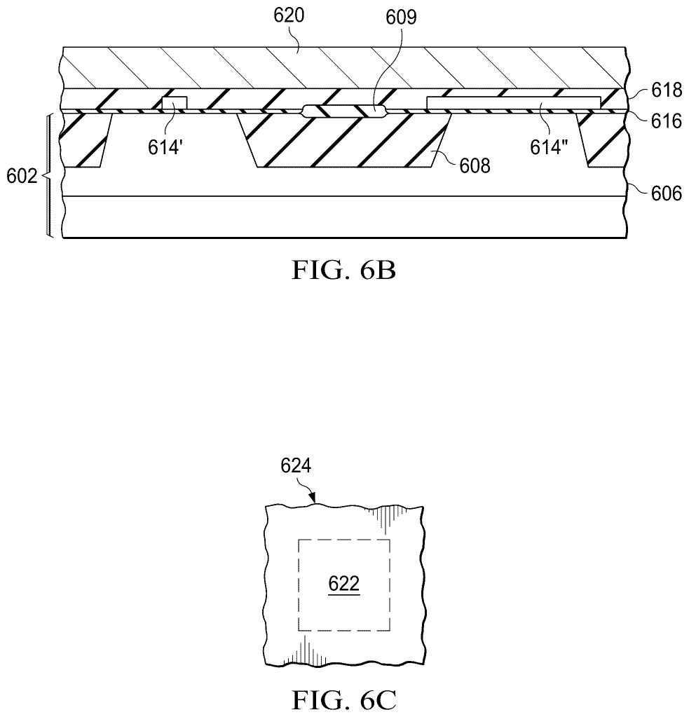

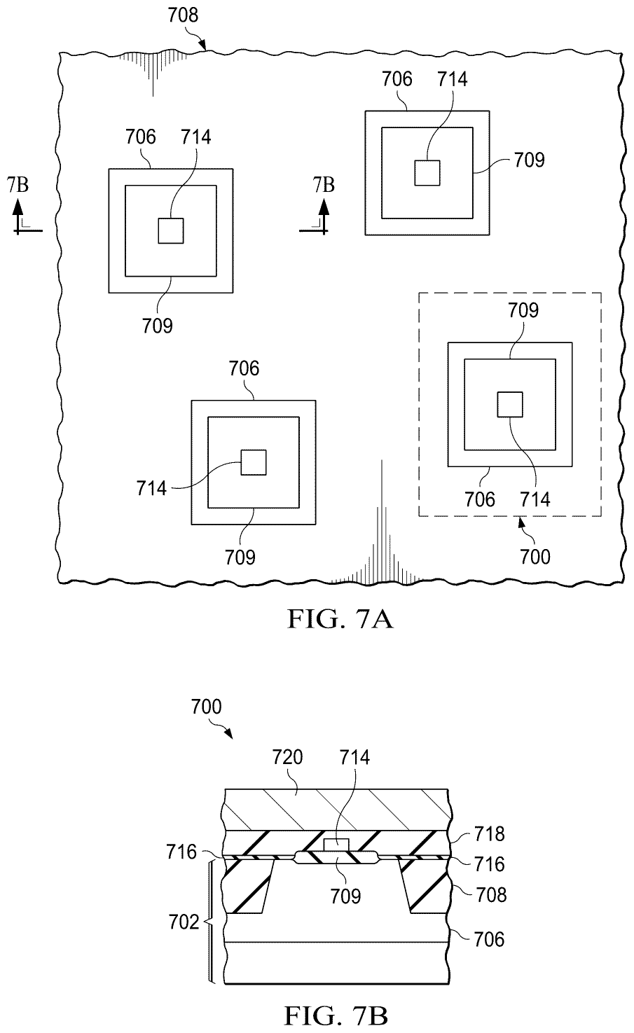

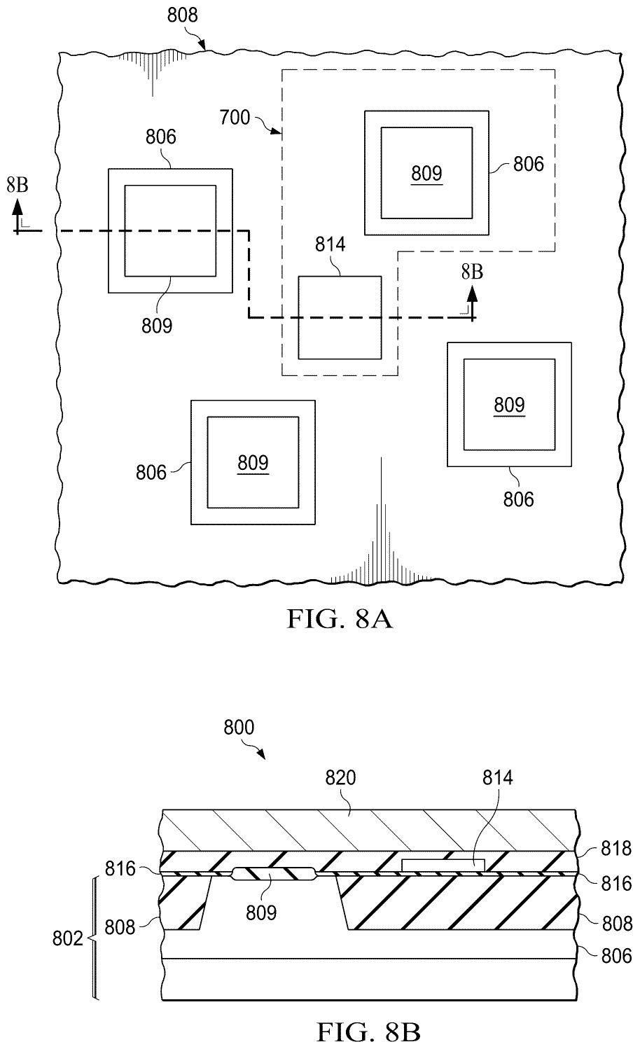

The inventors have discovered that the aforementioned weakness of the dummy cell structure 300 may be reduced or eliminated by one or more dummy cell structures that eliminate the cross-over of the bird's beak and the polysilicon structure that is part of the dummy cell structure. Specifically, FIGS. 6A-6C show an example dummy cell structure 600, FIGS. 7A and 7B show an example dummy cell structure 700 and FIGS. 8A and 8B show an example dummy cell structure 800, each of which shows an example that eliminates the cross-over.

FIG. 6A shows a plan view of the dummy cell structure 600 in which openings in an STI region 608 provide epitaxial (or MOAT) regions 606 at a top surface of a semiconductor substrate 602 (FIG. 6B). Polysilicon layers 614 are configured in a cross configuration over corresponding ones of the epitaxial region 606. A LOCOS layer 609 is laterally translated with respect to the epitaxial region 606, which places it entirely over the STI region 608. (It is noted that the LOCOS layer 609 will be thinner than a LOCOS layer formed on a silicon layer due to the presence of the STI region 608.) FIG. 6B shows a view of an offset section through two instances of the polysilicon layer 614, denoted 614′ and 614″, and one instance of the LOCOS layer 609. This section view additionally shows a gate dielectric layer 616 between the polysilicon layers 614 and the substrate 602. Notably, polysilicon layers 614′ and 614″ do not cross or intersect the edge of any LOCOS layer 609 (at which the bird's beak forms), and the bird's beak area is not over the epitaxial layer 606. Thus the polysilicon layers 614 are entirely planar (with the exception of inherent topography of the surface of the substrate 602, e.g. at the perimeter of the openings of the STI region 608). A PMD layer 618 is located over the polysilicon layers 614 and the LOCOS layer 609, and a metal layer 620 is located on the PMD layer 618. The metal layer 620 may be a signal trace, e.g. in an active area of an integrated circuit, or may be a test pad or bond pad, e.g. in a buffer area of the integrated circuit.

The dummy cell components may be placed at a density that meets desired areal density of the polysilicon layer, the epitaxial layer (or conversely the STI layer) and the LOCOS layer, and positioned anywhere within the active area of the integrated circuit 200. The dummy cell structure 600 may be particularly beneficial when placed within the buffer area 204 when high voltage signals are expected to be delivered to bond or probe pads. FIG. 6C illustrates a variation of the dummy cell structure 600 in which the polysilicon layer 614 overlies the epitaxial region 606 such that the perimeter of the polysilicon layer 614 completely surrounds the perimeter of the epitaxial region 606. This configuration may provide a greater areal density of the polysilicon layer 614 which may be advantageous in some process spaces in which such greater areal density results in better endpoint detection and/or etch process margin.

FIG. 7A shows a plan view of the dummy cell structure 700 in which openings in an STI region 708 provide epitaxial (or MOAT) regions 706 at a top surface of a semiconductor substrate 702 (FIG. 7B). A polysilicon layer 714 is located over LOCOS layer 709, but has a lateral area smaller than a lateral area of the LOCOS layer 709 such that the perimeter of the polysilicon layer 714 never crosses the perimeter of the LOCOS layer at which the bird's beak is located. Similar to the dummy cell structure 300, the LOCOS layer is over epitaxial (or MOAT) region 706. FIG. 7B is a section view of the layout of FIG. 7A through one instance of the polysilicon layer 714, one instance of the epitaxial region 706 and one instance of the LOCOS region 709. As was the case for the dummy cell structure 600, the polysilicon layer 714 does not extend to the edges of LOCOS layer 709, and thus avoids the bird's beak area. The polysilicon layer 714 is entirely planar by virtue of being located on the planar portion of the LOCOS layer 709. In some other examples, the polysilicon layer 714 may extend onto the portion of the LOCOS layer that becomes thinner, and thus nonplanar, towards the perimeter of the LOCOS layer, but does not extend to the bird's beak at the perimeter. As for the example of FIG. 6B, a gate dielectric layer 716 is located between the substrate 702 and a PMD layer 718, and a metal layer 720 that may be a signal trace, bond pad or probe pad is located on the PMD layer 718.

FIG. 8A shows a plan view of the dummy cell structure 800 in which openings in an STI region 808 provide epitaxial (or MOAT) regions 806 at a top surface of a semiconductor substrate 802 (FIG. 8B). LOCOS layer 809 is located over the epitaxial region 806 and a polysilicon layer 814 is laterally translated with respect to the epitaxial region 806 such that the polysilicon layer 814 is located over the STI region 808. By virtue of this translation the perimeter of the polysilicon layer 814 never crosses the perimeter of the LOCOS region 809, thus avoiding the bird's beak. FIG. 8B is a side view diagram of the layout of FIG. 8 through one instance of the polysilicon layer 814, one instance of the epitaxial region 806 and one instance of the LOCOS region 809. As shown, a gate dielectric layer 816 is located between the polysilicon layer 814 and the STI region 808, though in a fabricated device any oxide grown on the STI region 808 may be considered part of the STI region 808. Thus in this configuration the polysilicon layer 814 is considered to be directly on the STI region 808, and is entirely planar. As for the examples of FIGS. 6B and 7B, a PMD layer 718 overlies the polysilicon layer 814, and a metal layer 820 that may be a signal trace, bond pad or probe pad is located on the PMD layer 718.

In summary, in each of the dummy cell structures 600, 700 and 800 the corresponding polysilicon layer is located such that a perimeter of the polysilicon structure never crossed a perimeter, or bird's beak, of a LOCOS region, thereby eliminating the risk of dielectric breakdown between a metal layer over the dummy cell structures and the underlying substrate due to the presence of the LOCOS bird's beak. While these examples provide specific configurations of the polysilicon layers, epitaxial regions and LOCOS regions, other configurations are possible that prevent overlap of the polysilicon layer and the bird's beak, no particular feature is a requirement of such configurations unless explicitly recited in a particular claim.

What is claimed is:

1. An integrated circuit comprising:
a semiconductor substrate;
at least one dummy cell on the substrate, the dummy cell including:
an epitaxial region located within an opening in a shallow trench isolation (STI) region that extends into the substrate;
a local oxidation of silicon (LOCOS) region having a bird's beak at a perimeter of the LOCOS region; and
a polysilicon structure over the substrate,
wherein the polysilicon structure is located relative to the LOCOS region such that a perimeter of the polysilicon structure never crosses the perimeter of the LOCOS region.

2. The integrated circuit of claim 1, wherein the perimeter of the LOCOS region surrounds the perimeter of the polysilicon structure.

3. The integrated circuit of claim 1, wherein the LOCOS region is located on the STI region.

4. The integrated circuit of claim 1, wherein the polysilicon structure is located over the STI structure.

5. The integrated circuit of claim 4, wherein the polysilicon structure is located on the STI structure and over the epitaxial region.

6. The integrated circuit of claim 1, wherein the polysilicon structure is located entirely over the STI structure.

7. The integrated circuit of claim 1, further comprising a pre-metal dielectric (PMD) layer over the polysilicon structure and a metal layer on the PMD layer over the polysilicon structure.

8. The integrated circuit of claim 7, wherein the metal layer is a bond pad or a probe pad.

9. The integrated circuit of claim 1, wherein a perimeter of the polysilicon structure completely surrounds the perimeter of the LOCOS region.

10. The integrated circuit of claim 1, wherein the polysilicon structure is entirely planar.

11. A method of forming and integrated circuit comprising:
forming dummy cell over a semiconductor substrate, including:
forming a shallow trench isolation (STI) region extending into the semiconductor substrate;
forming a local oxidation of silicon (LOCOS) region over the semiconductor substrate; and
forming a polysilicon structure over the substrate,
wherein the polysilicon structure is located relative to the LOCOS region such that a perimeter of the polysilicon structure and a perimeter of the LOCOS region do not intersect.

12. The method of claim 11, wherein the perimeter of the LOCOS region surrounds the perimeter of the polysilicon structure.

13. The integrated circuit of claim 1, wherein the LOCOS region is located on the STI region.

14. The method of claim 11, wherein the polysilicon structure is located over the STI region.

15. The method of claim 14, wherein the polysilicon structure is located on the STI region and over an epitaxial region that extends to a top surface of the substrate.

16. The method of claim 11, wherein the polysilicon structure is located entirely over the STI region.

17. The method of claim 11, further comprising forming a pre-metal dielectric (PMD) layer over the polysilicon structure and a metal layer on the PMD layer over the polysilicon structure.

18. The method of claim 17, wherein the metal layer is a bond pad or a probe pad.

19. The method of claim 11, wherein a perimeter of the polysilicon structure completely surrounds the perimeter of the LOCOS region.

20. The method of claim 11, wherein the polysilicon structure is entirely planar.
